(19) United States
(12) Patent Application Publication
(10) Pub. No.: US 2022/0141954 A1
(43) Pub. Date: May 5, 2022

(54) Carrier with Downsized Through-Via

(71) Applicant: OSRAM Opto Semiconductors GmbH, Regensburg (DE)

(72) Inventor: Michael Schumann, Neu-Ulm (DE)

(21) Appl. No.: 17/600,943

(22) PCT Filed: Mar. 19, 2020
(86) PCT No.: PCT/EP2020/057673

§ 371 Date: Oct. 1, 2021

(30) Foreign Application Priority Data
Apr. 4, 2019 (DE) 10 2019 108 870.4

(51) Int. Cl. H05K 1/11; H01L 25/075; H01L 33/62; H05K 3/40; H05K 3/10

(52) U.S. Cl. CPC H05K 1/113; H01L 25/0753; H01L 33/62; H05K 1/053; H05K 3/103; H05K 3/107; H05K 3/4038

(57) ABSTRACT

In an embodiment a carrier includes a base substrate, at least one insulating layer, at least one inner wiring layer, at least one outer wiring layer and at least one through-via in the insulating layer extending through the insulating layer, wherein the base substrate and the insulating layer are formed from different materials, wherein the base substrate is formed for mechanically stabilizing the carrier and supports the insulating layer, wherein the inner wiring layer is arranged in a vertical direction at least in places between the base substrate and the insulating layer, wherein the outer wiring layer is spatially separated from the inner wiring layer at least in places by the insulating layer, and wherein the through-via electrically conductively connects the inner wiring layer to the outer wiring layer and has a lateral cross-section having a maximum lateral extent of at most 100 μm.

This patent application is a national phase filing under section 371 of PCT/EP2020/057673, filed Mar. 19, 2020, which claims the priority of German patent application 102019108870.4, filed Apr. 4, 2019, each of which is incorporated herein by reference in its entirety.

### TECHNICAL FIELD

A carrier with downsized through-via is disclosed.

### BACKGROUND

A printed circuit board is a carrier for electrical or electronic components and usually has a mounting surface comprising a plurality of connection pads, conductor tracks and closure caps. Their spacing from each other and their arrangement on the mounting surface are limited by minimum structural widths of the connection pads, conductor tracks and closure caps. Depending on the complexity of the wiring, a printed circuit board can be formed as a single-layer, double-layer or multilayer printed circuit board. A vertical connection between the layers is achieved in particular by through-vias, whose minimum diameter is often greater than 125 μm or greater than 150 μm in conventional producing processes. A closure cap covering the associated through-via thus has an even larger diameter, which is usually significantly larger than the minimum structure width of a layer. These typical structure widths and dimensions limit the design of the mounting surface and, in particular, the packing density of the components. Furthermore, difficulties arise in connecting components with closely spaced contact surfaces.

### SUMMARY

Embodiments provide a carrier which is suitable for accommodating electrical or electronic, in particular, optoelectronic components and has a particularly compact mounting surface for accommodating the largest possible number of components. Further embodiments provide a reliable and cost-efficient method for producing such a carrier.

Embodiments provide a carrier having a base substrate. In particular, the base substrate is formed with respect to its material composition and/or its layer thickness such that it mechanically supports and/or mechanically stabilizes the carrier. If the carrier has a plurality of further layers, these layers are also mechanically supported in particular by the base substrate. Of all the layers of the carrier, in particular the base substrate exhibits the highest mechanical stability. The base substrate can be a printed circuit board, a metal core board, a plastic body or a ceramic body. In particular, the base substrate has a plurality of glass fibers, which are for instance woven together and/or stacked on top of each other, and for instance embedded in an epoxy resin or epoxy-like resin. It is possible that the base substrate is formed from laminated layers of pre-impregnated fiber layers, so-called prepreg layers. Preferably, the base substrate is producible in a panel.

According to at least one embodiment of the carrier, it comprises an inner wiring layer and an outer wiring layer. In particular, the inner wiring layer is arranged on the base substrate, wherein a direct arrangement of the inner wiring layer on the base substrate is preferred. In the vertical direction, the inner wiring layer is spatially separated from the outer wiring layer, for example, by an insulating layer of the carrier. The outer wiring layer may be formed on the insulating layer, preferably directly on the insulating layer. The insulating layer and the base substrate may have different material compositions and/or different layer thicknesses. For example, the insulating layer is applied onto the base substrate and in this sense is mechanically supported by the base substrate. Further preferably, both the insulating layer and the base substrate are electrically insulating.

According to at least one embodiment of the carrier, it has at least one through-via in the insulating layer, which extends throughout the insulating layer and electrically connects the inner wiring layer to the outer wiring layer. Since the base substrate is formed, in particular with regard to its layer thickness and material composition, in such a way that the carrier is mechanically stabilized mainly by the base substrate and is thus mechanically supported by the base substrate, the insulating layer can be formed to be particularly thin. Since the insulating layer is not or hardly configured for mechanically stabilizing the carrier, this design of the insulating layer allows a wide range of materials for the insulating layer.

Due to the low layer thickness of the insulating layer, the through-via can be formed throughout the insulating layer in a comparatively simple manner. For example, an opening is formed throughout the insulating layer and subsequently filled with an electrically conductive material for forming the through-via. Due to the low layer thickness of the insulating layer, the opening can be made correspondingly small without any difficulties in filling the opening, for example, with regard to wetting or capillary effects. In particular, the through-via has a lateral cross-section that has a maximum lateral extent or diameter of at most 100 μm, 90 μm, 80 μm, 75 μm or of at most 50 μm. Further preferably, this maximum lateral extent or diameter is between 10 μm and 100 μm, inclusive.

A lateral direction is understood in the present context to be a direction parallel to a main extension surface of the carrier and/or of the base substrate, for example parallel to a mounting surface of the carrier. A vertical direction is herein understood to be a direction that is perpendicular to the main extension surface of the carrier and/or of the base substrate, for example perpendicular to the mounting surface of the carrier. The vertical direction and the lateral direction are arranged transversely or preferably orthogonally to each other.

In at least one embodiment of the carrier, it comprises a base substrate, at least one insulating layer, at least one inner wiring layer, at least one outer wiring layer, and at least one through-via in the insulating layer. In particular, the through-via extends throughout the insulating layer. Preferably, the base substrate and the insulating layer are formed of different materials. The base substrate is configured to mechanically stabilize the carrier and, in particular, supports the insulating layer. The inner wiring layer is arranged in the vertical direction at least in places between the base substrate and the insulating layer. The outer wiring layer is spatially separated from the inner wiring layer at least in places by the insulating layer. The through-via connects the inner wiring layer to the outer wiring layer in an electrically conductive manner. Particularly preferably, the through-via has a lateral cross-section with a maximum lateral extent of at most 100 μm.

The carrier thus has at least two different wiring layers which are separated from one another by a thin insulating layer and are electrically conductively connected to one another by the through-via. Since the carrier is formed at least in a double-layered manner, the outer wiring layer, whose surface in particular forms a mounting surface of the carrier, can have larger connection pads or a higher number of connection pads for accommodating a higher number of components. Since the wiring is realized in places via the through-via or via a plurality of through-vias, the number of conductor tracks on the mounting surface can be reduced. Since the through-via also has a comparatively small lateral cross-section, a closure cap of the through-via on the mounting surface can be formed to have smaller size.

Due to the multilayer design of the carrier and to the comparatively small dimensions of the through-via, more free space thus advantageously remains on the mounting surface for the formation of connection pads for receiving electrical components which are mounted on these connection pads. It is possible that the closure caps are formed as connection pads. Due to the reduced number of required conductor tracks and the reduced size of the closure caps, the mounting surface can have more or larger connection pads on which the components can be mounted. In this sense, the carrier may have a particularly compact design and/or accommodate a higher number of components.

According to at least one embodiment of the carrier, the inner wiring layer is arranged on the base substrate. In particular, the wiring layer is formed in a structured manner such that the insulating layer is directly adjacent to the base substrate in regions and directly adjacent to the inner wiring layer in other regions. For example, the inner wiring layer is formed from a structured cover layer of the base substrate. The structured cover layer of the base substrate may be divided into a plurality of spatially separated or interconnected subregions. These sub-regions may be in the form of conductor tracks and/or closure caps.

Corresponding to the inner wiring layer, the outer wiring layer may be formed as a structured cover layer comprising a plurality of connection pads, closure caps and/or conductor tracks. The outer wiring layer may be formed directly on the insulating layer. The through-via or the plurality of through-vias extend throughout the insulating layer, as a result of which the inner wiring layer is electrically conductively connected to the outer wiring layer. In particular, the size or geometry of the inner wiring layer is different from the size or geometry of the outer wiring layer. The closure caps of the outer wiring layer may be made larger or smaller than the corresponding closure caps of the inner wiring layer.

According to at least one embodiment of the carrier, it includes a through-via in the base substrate, which is electrically conductive and extends in particular throughout the base substrate. This through-via is referred to below as base through-via. Particularly preferably, the base through-via has a larger lateral cross-section than the through-via in the insulating layer. For example, the base through-via in the base substrate has a cross-section with a maximum lateral extent or diameter of at least 100 μm, 125 μm, 150 μm or 200 μm.

In particular, the through-via in the base substrate is not adjacent to, or does not extend through, the insulating layer. Thus, a closure cap of the outer wiring layer that completely covers the through-via in the insulating layer in top view may have a smaller cross-section or a smaller maximum lateral extent than a corresponding closure cap of the inner wiring layer that completely covers the through-via in the base substrate in top view. The through-via in the base substrate has a lateral diameter that is at least 25%, 50%, 75%, 100% or at least 200% larger than a lateral diameter of the through-via in the insulating layer. In case of doubt, the lateral diameter is to be understood as the maximum lateral extent of the through-via.

According to at least one embodiment of the carrier, it comprises a further wiring layer. The inner wiring layer and the further wiring layer are arranged in particular on opposite surfaces of the base substrate. The inner wiring layer and the further wiring layer can be electrically conductively connected to one another via the through-via or via the through-vias in the base substrate. The further wiring layer may be formed as a further inner wiring layer of the carrier or as an outer, rear-side wiring layer of the carrier.

According to at least one embodiment of the carrier, it comprises a further insulating layer, a further inner wiring layer, a further outer wiring layer and one or a plurality of further through-vias in the further insulating layer. The further through-via or through-vias extend throughout the further insulating layer. The base substrate is arranged in the vertical direction between the inner wiring layers as well as between the insulating layers. The further through-via can electrically conductively connect the further inner wiring layer to the further outer wiring layer.

The through-via and the further through-via in the insulating layer and in the further insulating layer, respectively, may have diameters or maximum lateral expansions of the same order of magnitude. For example, the through-via or the further through-via has a maximum diameter of at most 100 μm, 75 μm or of at most 50 μm. Preferably, the carrier in this case is at least four-layered. In other words, the carrier has at least four wiring layers.

For example, the carrier has two inner wiring layers arranged directly on the base substrate, namely on two opposite surfaces of the base substrate. The carrier may have two outer wiring layers, each of which is accessible from the outside, for example, and each of which is arranged in particular directly on one of the insulating layers. It is conceivable that additional wiring layers and/or additional insulating layers are arranged between an inner and an outer wiring layer. Furthermore, it may be provided that one of the outer wiring layers forms the mounting surface of the carrier and the other of the outer wiring layers forms a rear side of the carrier facing away from the mounting surface. In particular, the base substrate is located along the vertical direction between the insulating layer and the further insulating layer. The insulating layers may be formed of the same material or of different materials.

According to at least one embodiment of the carrier, the through-via in the insulating layer and/or the further through-via in the further insulating layer have/has a lateral cross-section with a maximum lateral extent of at most 75 μm or of at most 50 μm. For example, the maximum lateral extent is between 10 μm and 100 μm inclusive, for example between 30 μm and 100 μm inclusive or between 50 μm and 100 μm inclusive.

Along the vertical direction, the through-via and/or the further through-via may have a constant cross-section, a constant diameter or a constant maximum lateral extent. In contrast, it is possible that the through-via in the insulating layer and/or the further through-via in the further insulating layer have a decreasing lateral cross-section with a correspondingly decreasing lateral dimension or diameter as the vertical distance from the base substrate increases. At an outer wiring layer, the cross-section, diameter or maximum lateral extent of the through-via or further through-via can thus be made smaller. As a result, the lateral extent of the closure cap or the connection pad, which covers, in particular completely covers the through-via in top view, can also be further reduced.

According to at least one embodiment of the carrier, the inner wiring layer has an inner closure cap which, in top view, completely covers the through-via in the base substrate. The inner closure cap may be directly adjacent to the through-via in the base substrate. The outer wiring layer may have an outer closure cap adjacent to the through-vias in the insulating layer, wherein the outer closure cap covers, in particular completely covers the through-via in top view. Here, preferably, a maximum lateral offset between the outer closure cap and the through-via in the insulating layer is smaller than a maximum lateral offset between the inner closure cap and the through-via in the base substrate. For example, the maximum lateral offset between the outer closure cap and the through-via can be smaller than the maximum lateral offset between the inner closure cap and the through-via in the base substrate by at least 10 μm, 25 μm, 50 μm or 100 μm.

Deviating from this, it is possible that the maximum lateral offset between the outer closure cap and the through-via in the insulating layer is larger than a maximum lateral offset between the inner closure cap and the through-via in the base substrate. In general, the outer closure cap may be simultaneously formed as a connection pad for receiving a component. For example, a contact point of the component may be attached, in particular soldered, to the connection pad.

The carrier may have a plurality of pairs of connection pads, each pair being configured for receiving, mechanically securing, and/or electrically contacting at least one component. The connection pads of each pair may be associated with different electrical polarities. Furthermore, a lateral distance between the connection pads of the same pair or of the different adjacent pairs may be smaller than a lateral structural width of the conductor tracks or of the closure caps of the same wiring layer, in particular on the mounting surface. For example, this lateral distance may be smaller than 200 μm, 160 μm, 100 μm, 50 μm, 30 μm or 20 μm.

According to at least one embodiment of the carrier, the outer wiring layer forms a freely accessible mounting surface, which is configured to receive and make electrical contact with one component or with several electrical components. The mounting surface is in particular planar. In this context, a planar mounting surface is understood to mean in particular a mounting surface which has no local depressions or elevations, or which has only local depressions or elevations smaller than 50 μm, 40 μm, 30 μm, 20 μm or smaller than 10 μm. In particular, the mounting surface is formed in places by a surface of the insulating layer and in places by a surface of the outer wiring layer.

The planar mounting surface may have small local depressions or elevations, whose vertical depth or height is given by the vertical layer thickness of the outer wiring layer or is smaller than the vertical layer thickness of the outer wiring layer, i.e. is smaller than the layer thickness of the conductor tracks, the connection pads and/or the closure caps of the outer wiring layer. Along the vertical direction, the insulating layer may protrude in places beyond the outer wiring layer, or vice versa.

The carrier has a rear side facing away from the mounting surface. The rear side of the carrier may be formed in places by a surface of the further insulating layer and in places by a surface of the further outer wiring layer. Analogous to the mounting surface, the rear side of the carrier may be planar.

According to at least one embodiment of the carrier, the outer wiring layer has a plurality of conductor tracks and connection pads arranged next to one another. In particular, the outer wiring layer forms the mounting surface of the carrier. Preferably, the connection pads are densely packed, wherein a lateral distance between adjacent connection pads is in particular not greater than a minimum structural width of the conductor tracks and/or closure caps. Preferably, the mounting surface is free of conductor tracks and/or closure caps which, in top view, are arranged at least regionally between adjacent connection pads, for example between two adjacent rows or columns of connection pads, while being laterally spaced from these connection pads. For example, some of the connection pads are not via the through-vias in the insulating layer but exclusively via the conductor tracks of the outer wiring layer externally electrically contactable. This means that these connection pads are wired externally, in particular via the conductor tracks, and can thus be electrically conductively connected to an external voltage source. Some further of the connection pads, in particular the remaining of the connection pads, are electrically conductively connected to the inner wiring layer, for example, by the through-vias in the insulating layer.

The further connection pads can be wired to the outside via the inner wiring layer, for example via conductor tracks of the inner wiring layer and/or via through-via/s in the base substrate and/or via further through-via/s in the further insulating layer. Wiring of a connection pad to the outside means that the connection pad can be electrically contacted externally. If a connection pad is wired to the outside, it can be connected to an external voltage source, for example. Thus, the external electrical contacting of the connection pads on the mounting surface takes place on at least two, three or four wiring layers.

According to at least one embodiment of the carrier, at least some or all of the adjacently arranged connection pads are arranged as pairs. The connection pads of the same pair can be assigned to different electrical polarities of the carrier. In particular, in each case, one connection pad of a pair cannot be electrically contacted externally via the through-via but exclusively via conductor track/s of the outer wiring layer. The other connection pad of each pair is preferably electrically conductively connected to the inner wiring layer by a through-via in the insulating layer. In particular, the pair of connection pads is set up for receiving, mechanically fastening and/or electrically contacting a component.

It is further possible that at least one of the connection pads is electrically conductively connected from the inner wiring layer to the further inner wiring layer via the through-via in the base substrate. Via the further through-via in the further insulating layer, this connection pad can be wired to the further outer wiring layer, in particular wired to the outside. It is also possible that one of the connection pads of the same pair is wired to the outside exclusively via a conductor track on the mounting surface, while the other connection pad of the same pair is not electrically conductively connected to any of the conductor tracks on the mounting surface, but is at least partially wired via the through-via/s in the insulating layer and/or in the base substrate and/or in the further insulating layer.

According to at least one embodiment of the carrier, it has a plurality of through-vias in the insulating layer. The outer wiring layer may have a plurality of conductor tracks, which are in particular arranged on the edge side of the mounting surface. For example, the outer wiring layer has a plurality of electrically conductor tracks and a plurality of pairs of adjacent connection pads. At least some of the connection pads may be electrically conductively connected to the electrical conductor tracks. It is possible that the other connection pads are each electrically conductively connected to one of the through-vias in the insulating layer. The connection pads that are electrically conductively connected to the through-vias in the insulating layer are not electrically conductively connected to the conductor tracks on the mounting surface, for example. These connection pads are electrically contacted in particular by the through-vias in the insulating layer with the underlying wiring layer and in particular are electrically contacted externally from there.

The electrical contacting of the connection pads arranged on the same mounting surface can thus take place on different wiring layers. The number of electrical conductor tracks and/or of closure caps on the mounting surface can thus be reduced, since the electrical contacting of some connection pads takes place via the through-vias located underneath. The mounting surface can thus have a higher number of closely packed connection pads, as a result of which a higher number of components can be arranged on the mounting surface. The components can thus be arranged particularly close together on the mounting surface. Since the electrical contacting of the connection pads or of the components takes place via different wiring layers, the risk of electrical short circuits on the mounting surface is reduced.

According to at least one embodiment of the substrate, the insulating layer and/or the further insulating layer is a layer of a potting compound, an oxide layer, a nitride layer, a polyimide layer, a solder resist layer or a photoresist layer. The base substrate may be a printed circuit board, a metal core board, a plastic body, or a ceramic body.

Further embodiments provide a method for producing a carrier, in particular, a carrier described herein. The features described in connection with the carrier can therefore also be used for the method, and vice versa.

According to at least one embodiment of the method, a carrier having a base substrate, an insulating layer, an inner wiring layer, an outer wiring layer and a through-via extending throughout the insulating layer is produced. Via the through-vias in the insulating layer, the inner wiring layer is electrically connected to the outer wiring layer. The through-via in the insulating layer has a lateral cross-section whose maximum lateral extent is preferably at most 100 μm.

According to at least one embodiment of the method, the process for forming the base substrate and the process for forming the insulating layer differ from each other. For example, the base substrate is provided as a printed circuit board, a ceramic body, a plastic body, or a metal core board. The process for forming the insulating layer may include steps of applying the insulating layer to the base substrate and structuring the insulating layer to form the through-vias. For example, the insulating layer is applied onto the base substrate by a coating process. The base substrate may be formed by a casting process or by laminating a plurality of electrically insulating and/or electrically conductive layers. It is possible that the base substrate is provided as a prefabricated printed circuit board.

The base substrate may have a preliminary mounting surface with connection pads, conductor tracks and/or closure caps. By applying the insulating layer or insulating layers, the preliminary mounting surface is covered. The final mounting surface of the carrier is formed only after the outer wiring layer is applied onto the insulating layer. The mounting surface of the carrier may differ from the preliminary mounting surface of the base substrate in terms of the number and/or in terms of the geometry and size of the conductor tracks, of the connection pads and/or of the closure caps.

According to at least one embodiment of the method, an electrically insulating material is applied onto the inner wiring layer to form the insulating layer. An opening is formed in the insulating layer to partially expose the inner wiring layer, whereupon the opening is filled with an electrically conductive material for forming the through-via. A mechanical process, a chemical process, such as an etching process, or a laser drilling process may be used to form the opening or a plurality of openings. If the insulating layer is formed of a photostructurable material, such as a photoresist, the openings in the insulating layer may be formed by exposure to light, in particular using a mask.

According to at least one embodiment of the method, an electrically conductive material for forming the through-vias is applied in places to the inner wiring layer prior to forming the insulating layer. An electrically insulating material can be applied to the inner wiring layer to form the insulating layer, so that the insulating layer covers, in particular completely covers the through-via in top view. To expose the through-vias, the material of the insulating layer can be partially removed.

In this variant of embodiment, the through-via or the plurality of through-vias is/are applied to the wiring layer before the insulating layer is applied. In this case, the through-via is formed as a local elevation on the wiring layer before the insulating layer is applied to the wiring layer. Since the through-via or the through-vias is/are formed before the insulating layer, there is no need to form openings in the insulating layer and then fill them. In this case, the through-vias can each have a particularly small cross-section or diameter, since the difficulties of filling particularly small openings do not arise in this case.

In this case, the through-via or the through-vias may be formed in a drop-shape or hemispherical shape on the corresponding wiring layer. Such through-vias may each have a cross-section that tapers with increasing distance from the base substrate or from the corresponding wiring layer.

### BRIEF DESCRIPTION OF THE DRAWINGS

Further embodiments and further developments of the carrier or of the method for producing the carrier will be apparent from the embodiments explained below in connection with FIGS. 1A to 10D.

FIGS. 1A, 1B and 1C show schematic representations of various comparative examples of a conventional carrier in vertical sectional view;

FIGS. 1D and 1E show schematic representations of various comparative examples of a conventional carrier in top view;

FIGS. 2A, 2B and 2C show schematic representations of a carrier in vertical sectional view;

FIGS. 3A and 3B show schematic representations of further exemplary embodiments of a carrier in vertical sectional view;

FIG. 3C shows schematic representation of a section of a carrier in vertical sectional view;

FIGS. 4A, 4B and 4C show schematic representations of various exemplary embodiments of a four-layer carrier in vertical sectional view;

FIGS. 4D and 4E show schematic representations of further exemplary embodiments of a multilayer carrier in vertical sectional view;

FIGS. 5A, 5B and 5C show schematic representations of a carrier, where 5A is a top view of the mounting surface, 5B is a vertical sectional view, 5C is a top view of the inner wiring position;

FIGS. 6A and 6B show schematic representations of another exemplary embodiment of a carrier, where 6A is a top view of the mounting surface and 6B is a top view of the inner wiring position;

FIGS. 7A and 7B show schematic representations of a further exemplary embodiment of a carrier, where 7A is a top view of the mounting surface and 7B is a top view of the inner wiring position;

FIGS. 8A, 8B, 8C, 8D, 8E, 8F and 8G show schematic representations of various method steps of a process for producing a carrier, each in vertical sectional view;

FIGS. 9A, 9B and 9C show schematic representations of various method steps of a process for producing a carrier according to a further exemplary embodiment, in each case in vertical sectional view; and

FIGS. 10A, 10B, 10C and 10D show schematic representations of further method steps of a process for producing a carrier, in each case in vertical sectional view.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

### DETAILED DESCRIPTION OF ILLUSTRATIVE EMBODIMENTS

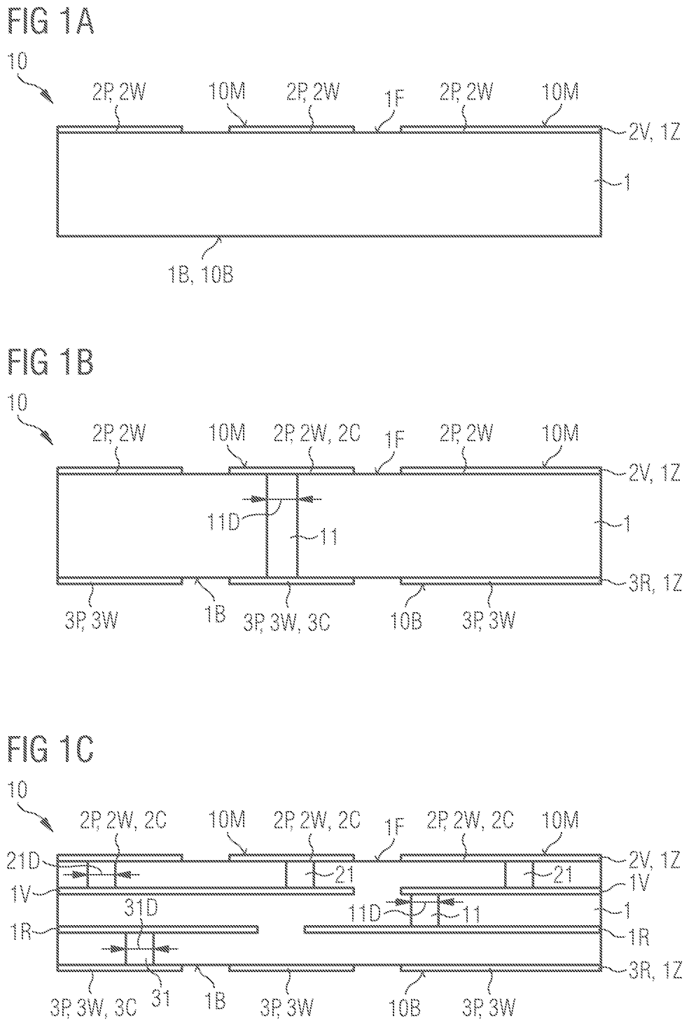

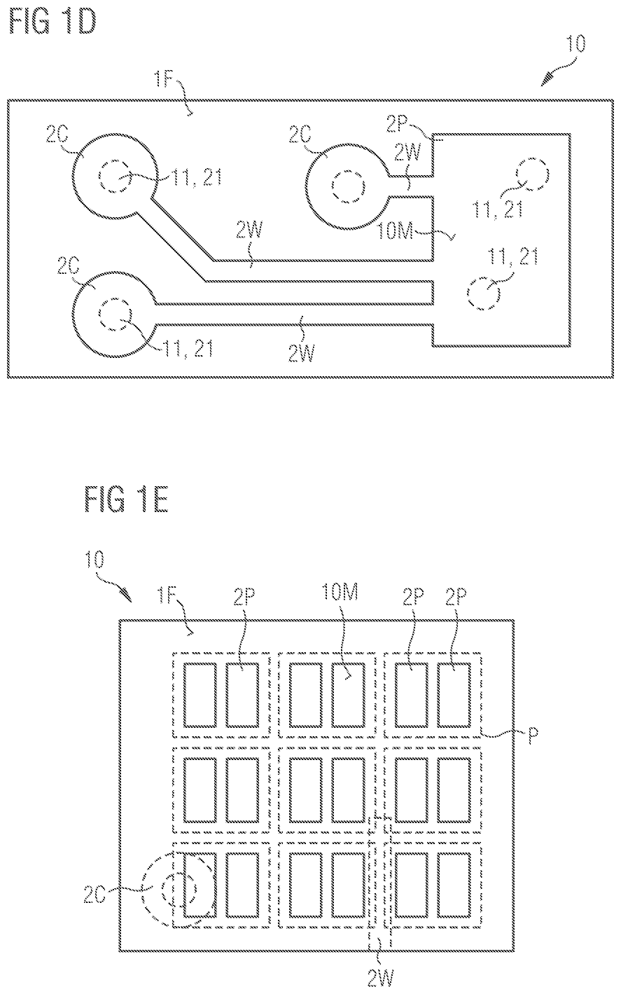

FIG. 1A shows a comparative example of a single-layer conventional carrier 10. The carrier 10 has a base substrate 1. A wiring layer 2V is arranged on the base substrate 1. A mounting surface 10M of the carrier 10 is formed by exposed surfaces of the base substrate 1F and by exposed surfaces of the wiring layer 2V. The carrier 10 also has an exposed rear side 10B facing away from the mounting surface 10M, which is formed by a rear-side surface 1B of the base substrate 1.

In particular, the wiring layer 2V is formed by a structured covering layer 1Z of the base substrate 1. The structured covering layer 1Z may have a plurality of interconnected sub-regions or laterally spaced sub-regions, for example, in the form of conductor tracks 2W or connection pads 2P or other structures on the mounting surface 10M.

FIG. 1B shows a comparative example of a two-layer conventional carrier 10 which, in comparison with FIG. 1A, additionally has a rear wiring layer 3R on the rear side 1B of the base substrate 1. This wiring layer 3R can, for example, fulfill the function of a rear-side connection, contact or mounting surface. The front side 1F and/or the rear side 1B may be planar.

The front-side wiring layer 2V can be formed from a structured cover layer 1Z of the base substrate 1, which has a plurality of sub-regions, which are formed, for example, as conductor tracks 2W, connection pads 2P or as closure caps 2C (cf. FIG. 1D). The rear-side wiring layer 3R can be formed analogously to the front-side wiring layer 2V by a structured cover layer 1Z which has a plurality of sub-regions, which are formed, for example, as rear-side connection pads 3P, as rear-side conductor tracks 3W or as rear-side closure caps 3C.

The front-side wiring layer 2V is electrically conductively connected to the rear-side wiring layer 3R via a through-via 11 or via a plurality of through-vias 11. The closure caps 2C or 3C within the wiring layers 2V or 3R represent the end points of the through-vias 11.

FIG. 1C shows a comparative example of a four-layer conventional carrier 10, which—compared to FIG. 1B—additionally has two inner wiring layers 1V and 1R. In particular, the front side 1F or the rear side 1B together with the wiring layer 2V or 3R is planar. The inner wiring layers 1V and 1R are embedded in the same material of the base substrate 1.

Via the through-vias 21 and 31, the outer wiring layers 2V and 3R can be electrically conductively connected to the inner wiring layers 1V and 1R. The two inner wiring layers 1V and 1R may be electrically conductively connected to each other via the through-via/s 11.

In the carriers 10 shown in FIGS. 1A to 1C, the connection pads 2P are part of the mounting surface 10M for external contacting. They should therefore have a suitable minimum structural width and spacing so that an electrical component can be securely mounted on the mounting surface and electrically contacted. The connection pads 3P (if present) are part of rear side 10B of the carrier for external contacting. Therefore, they should have a suitable minimum structural width and spacing so that the carrier 10 can be securely mounted on and suitably electrically connected to a sub-mount.

The carriers 10 shown in FIGS. 1A to 1C may each have a base substrate 1 made of an electrically insulating material, wherein the through-vias 11, 21 and/or 31 shown in FIGS. 1B and 1C are in particular embedded in the same material of the base substrate 1 and/or laterally surrounded by the same material of the base substrate 1.

The through-vias 11, 21 and 23 each have a lateral diameter 11D, 21D and 31D, respectively. In conventional methods using conventional materials of the base substrate, the through-vias 11, 21 and 31 generally have a diameter of at least 125 μm or 150 μm. The closure caps 1C, 2C or 3C should be of such a size that, in top view, they reliably completely cover the respective associated through-vias 11, 21 or 31, even taking into account process-related offset tolerances. The size of the through-vias 11, 21 or 31 thus plays an important role in the design of the carrier 10, in particular of the mounting surface 10M of the carrier 10.

In FIG. 1D, a section of a mounting surface 10M of a carrier 10 is shown in top view. In particular, the mounting surface 10M is formed from an exposed surface 1F of the base substrate 1 and from an exposed surface of the outer wiring layer 2V. Thus, the mounting surface 10M is electrically conductive in places and electrically insulating in places.

Referring to FIG. 1D, the mounting surface 10M has at least one connection pad 2P, usually a plurality of conductor tracks 2W, and usually a plurality of closure caps 2C. If a connection pad 2P covers a through-via 11 or 21, it additionally fulfills the function of a closure cap 2C. The closure cap 2C may be integrated, i.e. included or at least partially included, in the connection pad. In top view, the closure caps 2C (and, if applicable, the connection pad 2P) completely cover the respective associated through-via 11 or 21.

The conductor tracks 2W have a minimum structural width (usually this is the conductor track width), which is given either by the producing process of the wiring layer 2V or by the application, for example, with respect to the required current carrying capacity.

The closure caps 2C have a minimum structure width (usually this is the cap diameter), which is given by the producing processes of the wiring layer 2V and of the through-vias 11 or 21.

There is a minimum distance between the connection pads 2P and/or the conductor tracks 2W and/or the closure caps 2C which is given either by the producing process of the wiring layer 2V or by the application, for example, in terms of the required dielectric strength.

Due to the presence of conductor tracks 2W and/or of closure caps 2C, as well as the minimum structure widths and minimum distances to be maintained, the design freedom of the connection pads 2P within the mounting surface 10M is limited, in particular with respect to their sizes and positions.

The designs of the wiring layer 2V, illustrated in FIG. 1D, apply analogously also to the outer wiring layer 3R and, excluding the connection pads, also to inner wiring layers.

If a dense regular arrangement of components on the mounting surface 10M is desired, the mounting surface 10M will usually have a regular arrangement of densely packed connection pads 2P, each having different electrical potentials. This may result in insufficient remaining free space on the mounting surface 10M for the required conductor tracks 2W or for the closure caps 2C to connect or to wire each of the connection pads 2P in an electrically suitable manner.

FIG. 1E illustrates an example of the problem of an arrangement of 6×3 connection pads 2P which is suitable for mounting 3×3 closely packed small bipolar components P. Due to the small component size, each connection pad 2P is too small to integrate a closure cap 2C therein. Due to the close packing of the components P, the spacing of the connection pads 2P is too small to allow conductor tracks to pass through between them. Consequently, in this example, the internal 4 of the total 18 connection pads cannot be electrically connected, neither by conductor track nor by through-via.

An arrangement of closely packed small components such as closely packed light emitting diode flip chips on the carrier 10 according to FIG. 1E is thus difficult to realize.

In the following, various exemplary embodiments of a carrier 10 are illustrated wherein the closure caps 2C can be reduced in size or the number of conductor tracks 2W and/or closure caps 2C on the mounting surface 10M can be reduced.

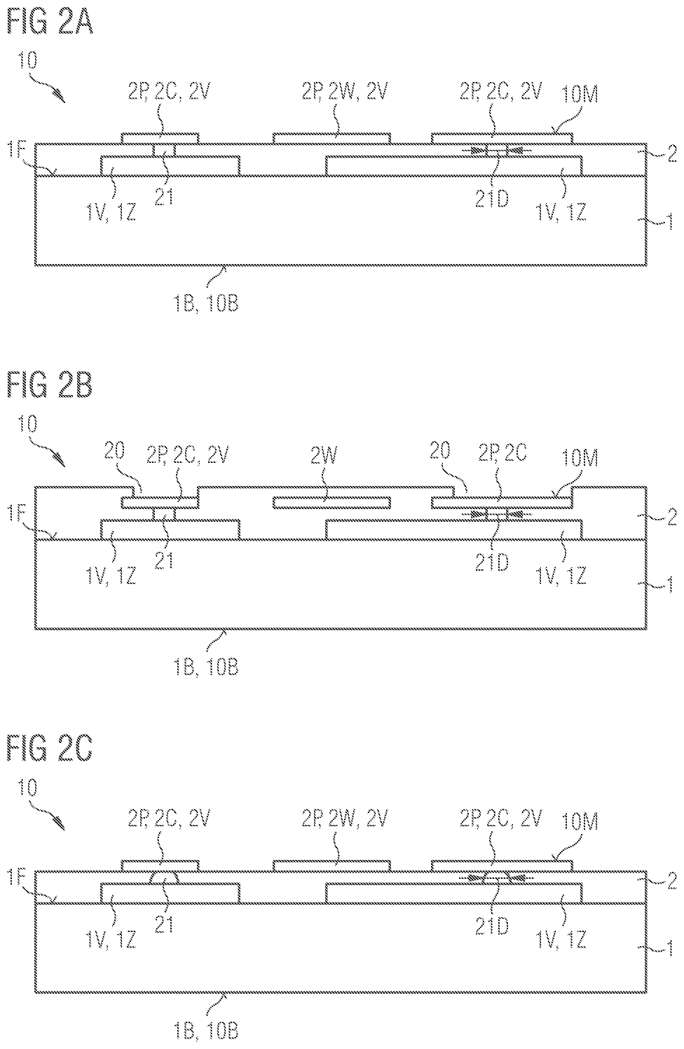

The exemplary embodiment for a carrier 10 shown in FIG. 2A is structurally similar to the carrier 10 shown in FIG. 1A. In contrast, the carrier 10 has an inner wiring layer 1V and an outer wiring layer 2V. An insulating layer 2 is arranged in places between the wiring layers 1V and 2V. The carrier 10 has a plurality of through-vias 21 that extend throughout the insulating layer 2 in places and electrically conductively connect the inner wiring layer 1V to the outer wiring layer 2V. In particular, the through-vias 21 each have a cross-section with a maximum lateral extent or with a lateral diameter of at most 100 μm.

Compared with conventional carriers (see for example FIG. 1A), the closure caps 2C and/or the connection pads 2P on the outer wiring layer 2V can be made correspondingly smaller. Referring to FIG. 2A, the outer wiring layer 2V projects beyond the insulating layer 2 along the vertical direction. The conductor tracks 2W, the closure caps 2C, the connection pads 2P and/or the through-vias 21 of the outer wiring layer 2V may be formed of the same material or of different materials. It is conceivable that the through-vias 21 and the associated closure cap 2C are formed of the same material and in one piece. Deviating from this, it is possible that the through-via 21 and the associated closure cap 2C are two different layers, which in particular are directly adjacent to one another and are produced in different method steps.

The mounting surface 10M is in particular planar and has a roughness of at most 50 μm, 40 μm, 30 μm, 20 μm or of at most 10 μm. In particular, the roughness of the mounting surface 10M is given by local depressions or local elevations, which are caused, for example, by the layer thickness of the conductor tracks 2W, the connection pads 2P and/or of the closure cap 2C. The conductor tracks 2W, the closure caps 2C and/or the connection pads 2P can have a vertical layer thickness of at most 50 μm, 40 μm, 30 μm, 20 μm or at most 10 μm.

The exemplary embodiment shown in FIG. 2B is essentially the same as the exemplary embodiment shown in FIG. 2A. In contrast, the insulating layer 2 extends beyond the outer wiring layer 2V in places. In this case, the insulating layer 2 may cover the closure caps 2C, the connection pads 2P in places, and the conductor tracks 2W completely. At positions of the connection pads 2P, the insulating layer 2 may have openings 20, so that the connection pads 2P are accessible in the openings 20 of the insulating layer 2. The connection pads 2P are configured to receive one or more components. The openings 20 may serve as a collecting basin for excess bonding material.

The exemplary embodiment shown in FIG. 2C essentially corresponds to the exemplary embodiment shown in FIG. 2A. The difference is that the cross-sections of the through-vias 21, in each case, decrease with increasing distance from the base substrate 1. Thus, the through-vias 21 have a smaller cross-section at the outer wiring layer 2V than at the inner wiring layer 1V.

According to the carriers 10 shown in FIGS. 2A to 2C, a rear side 10B is formed by a surface, in particular by a rear side 1B, of the base substrate 1.

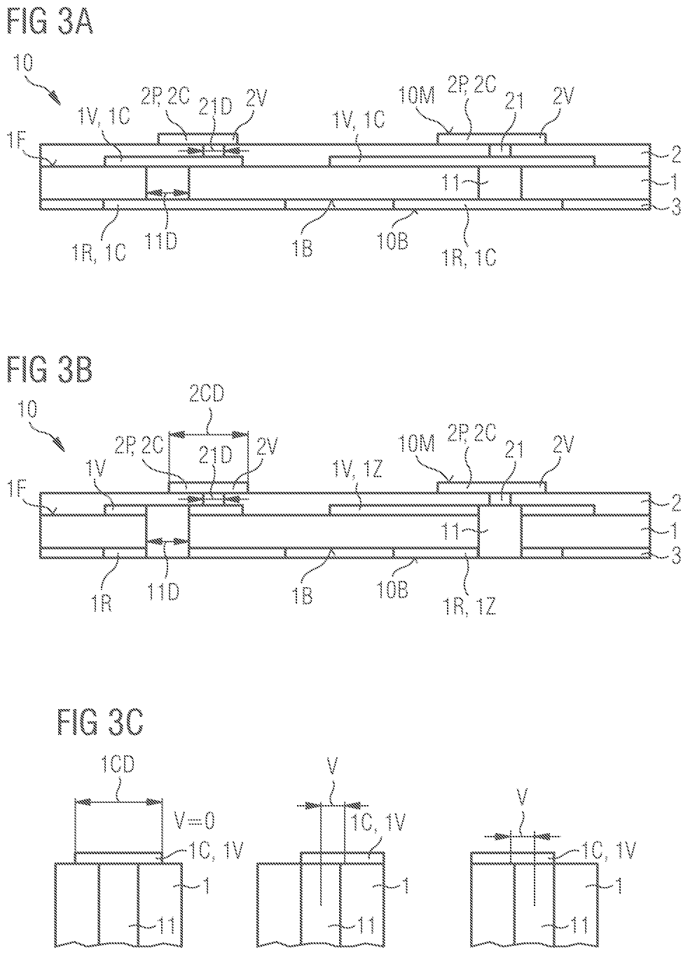

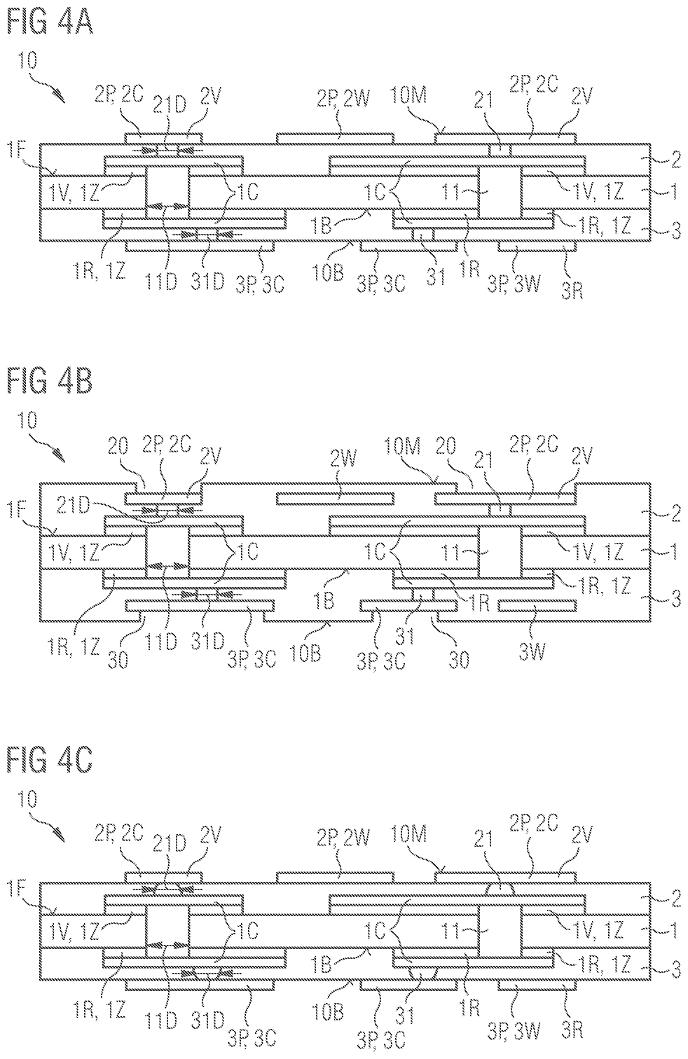

The exemplary embodiment shown in FIG. 3A is substantially the same as the exemplary embodiment shown in FIG. 2A. In contrast, the carrier 10 includes a plurality of base through-vias 11, wherein the through-vias 11 extend throughout the base substrate 1 along the vertical direction. The carrier 10 further comprises a rear-side wiring layer 1R having closure caps 1C on the rear side 1B of the base substrate 1. The base through-vias 11 thus extend from the rear-side wiring layer 1R throughout the base substrate 1 to the inner wiring layer 1V. The rear side 1B of the carrier 10 is formed in places by surfaces of the rear-side wiring layer 1R and in places by surfaces of a further insulating layer 3, wherein the insulating layer 3 is disposed on the rear side 1B of the base substrate 1. This insulating layer 3 may fill up regions between the closure caps 1C, so that as a whole, the rear side 1B is planar.

The base through-via 11 has a lateral diameter 11D. In case of doubt, the diameter 11D is a maximum lateral extent of the cross-section of the base through-via 11. In particular, the diameter 11D is greater than 100 μm, particularly greater than 150 μm. It is possible that the diameter 11D of the base through-via 11 is at least 50%, 75%, 100% or 200% larger than the diameter 21D of the through-via 21. In top view, the base through-via 11 and the through-via 21 may overlap, partially overlap, or be arranged side by side.

The exemplary embodiment shown in FIG. 3B is substantially the same as the exemplary embodiment shown in FIG. 3A. In contrast, the base through-vias 11 do not extend from the rear-side wiring layer 1R to the inner wiring layer 1V but throughout the rear-side wiring layer 1R and throughout the inner wiring layer 1V. While the through-via 21 in FIG. 3A is arranged on the inner wiring layer 1V, according to FIG. 3B, at least one of the through-vias 21 may be arranged directly on the base through-via 11 in top view. In top view, the through-via 21 is completely covered by a closure cap 2C whose diameter 2CD is larger than a diameter 21D of the through-via 21.

In FIG. 3C, a base through-via 11 in the base substrate 1 and an associated closure cap 1C on the base substrate 1 are schematically shown as an example. The base through-via 11 has a lateral diameter 11D. The closure cap 1C has a lateral diameter 1CD.

In top view, the closure cap 1C completely covers the associated base through-via 11. In ideal coverage, the closure cap 1C and the associated base through-via 11 may have the same cross-section or diameter. In practice, however, the diameter 1CD of the closure cap 1C is chosen to be the sum of the diameter 11D of the base through-via 11 and the producing tolerances. In general, the required diameter of the closure cap is preferably at least as large as the sum of the diameter of the through-via and twice the producing tolerances. For example, the diameter 1CD is at least 110 μm, 130 μm, 160 μm, 210 μm or 250 μm.

In FIG. 3C, the optimal positioning of the closure cap 1C on the base through-via 11 is schematically shown on the left side, i.e. with an offset V of zero. A possible maximum offset between the base through-via 11 and the associated closure cap 1C is schematically shown in the center and on the right side in FIG. 3C. The edge of the closure cap 1C coincides with the edge of the through-via 11, so that the closure cap 1C just completely covers the base through-via 11.

The example illustrated in FIG. 3C can be applied to all corresponding pairs of matched through-vias and closures, for example, vias 21 having a lateral diameter 21D and closures 2C having a lateral diameter 2CD.

Because the through-vias 21 in the insulating layer 2 can have a smaller cross-section compared to the base through-vias 11 in the base substrate 1, it is possible that the minimum required diameter 2CD of the closure cap 2C is correspondingly smaller than the diameter 1CD of the closure cap 1C for the same maximum offset, and that the required area of the closure cap 2C is correspondingly smaller in square than the area of the closure cap 1C.

For some producing processes, the maximum occurring offset correlates with the size of the through-via and/or of the closure cap, so that a smaller closure cap 2C can be placed on a through-via 21 with a smaller offset V. This in turn further reduces the minimum required diameter 2CD of the closure cap 2C.

For example, for a base through-via 11 having a diameter 11D of 125 μm and extending throughout the base substrate 1, the offset V may be 50 μm, so that the minimum required diameter 1CD of the closure cap 1C is 225 μm, while for a through-via 21 having a diameter 21D of 30 μm and extending throughout an insulating layer 2, the offset V may be 25 μm, so that the minimum required diameter 2CD of the closure cap 2C is only 80 μm. The minimum required area of the closure cap 2C would be 5027 μm², compared to 39761 μm² for the closure cap 1C.

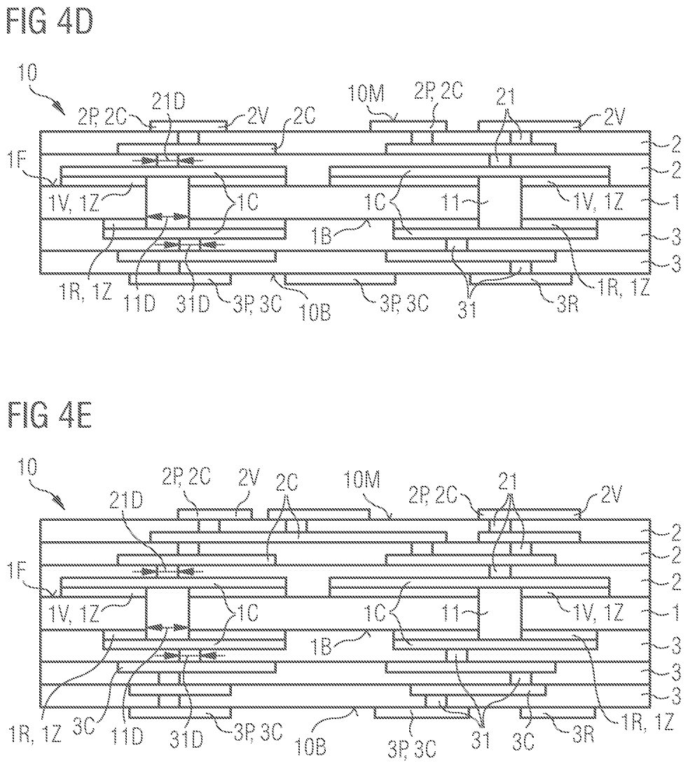

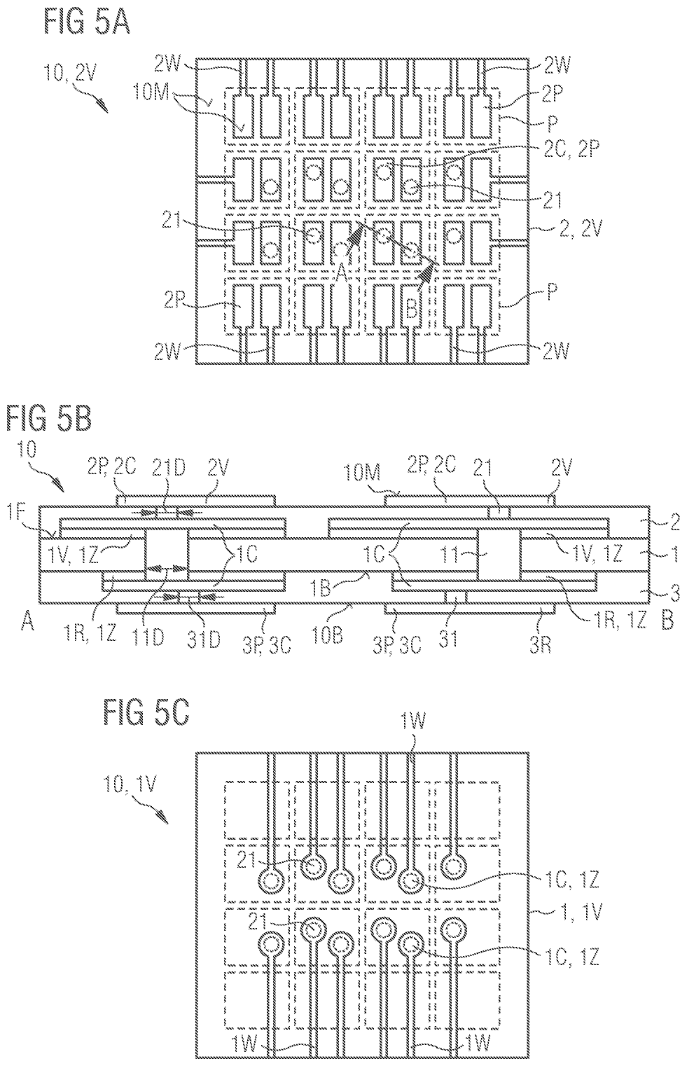

The exemplary embodiment shown in FIG. 4A is essentially the same as the exemplary embodiment shown in FIG. 3A. In contrast, the carrier 10 is four-layered. In addition to the inner wiring layer 1V and the outer wiring layer 2V, the carrier 10 has a further inner wiring layer 1R and a further outer wiring layer 3R. In addition, the inner wiring layers 1V and 1R each have a cover layer 1Z of the base substrate 1. The respective cover layers 1Z are arranged in particular on the base substrate 1, in particular directly on the base substrate 1. The base through-vias 11 extend in particular partially throughout the respective cover layers 1Z. The closure caps 1C are each arranged on the cover layer 1Z, in particular directly on the cover layer 1Z. The cover layers 1Z and the closure caps 1C can be congruent when viewed from above.

According to FIG. 4A, the carrier 10 has a further insulating layer 3. The insulating layer 3 may be formed analogously to the insulating layer 2. The carrier 10 has a plurality of further through-vias 31 which electrically conductively connect the further inner wiring layer 1R to the further outer wiring layer 3R. The outer wiring layer 3R is located on the rear side 10B of the carrier 10. The outer wiring layer 3R is thus accessible from the outside. Analogous to the front-side outer wiring layer 2V, the rear-side wiring layer 3R may have a plurality of conductor tracks 3W, closure caps 3C and/or connection pads 3P. In terms of material composition as well as of layer thickness, the outer wiring layer 3R may be formed analogously to the outer wiring layer 2V.

The exemplary embodiment shown in FIG. 4B essentially corresponds to the exemplary embodiment shown in FIG. 4A. In contrast, the insulating layers 2 and 3 in FIG. 4B are formed analogously to the insulating layer 2 in FIG. 2B. In other words, the insulating layers 2 and 3 may each have a plurality of openings 20 or 30, wherein the connection pads 2P or 3P are exposed. The conductor tracks 2W and/or 3W and the closure caps 2C and/or 3C may be partially or completely covered by the respective insulating layers 2 or 3. The connection pads 2P and/or 3P may be partially covered by the respective insulating layers 2 or 3.

The exemplary embodiment shown in FIG. 4C is substantially the same as the exemplary embodiment shown in FIG. 4A. In contrast, the through-vias 21 or 31 are formed such that their cross-section or diameter 21D or 31D decreases with increasing distance from the base substrate 1. The design of the through-vias 21 and 31 illustrated in FIG. 4C is analogous to the design of the through-vias 21 illustrated in FIG. 2C.

FIGS. 4D and 4E illustrate that further insulating layer layers and further wiring layers can be added on the mounting side and/or on the rear side.

Starting from a carrier shown in FIG. 1B without insulating layer and associated wiring layer, FIG. 4A shows on each side of the carrier an insulating layer 2 or 3 with associated wiring layer 2V or 3R. FIG. 4D shows two insulating layers 2 or 3 on each side with associated wiring layers. FIG. 4E shows three insulating layers 2 or 3 with associated wiring layers on each side. If further internal wiring layers are required, these can be arranged in the base substrate 1 and/or in the insulating layers 2 or 2, for example, as shown in FIG. 1C. The through-vias 21 and 31 between the wiring layers within the insulating layers 2 and 3 can be smaller than the base through-vias 11 in the base substrate 1.

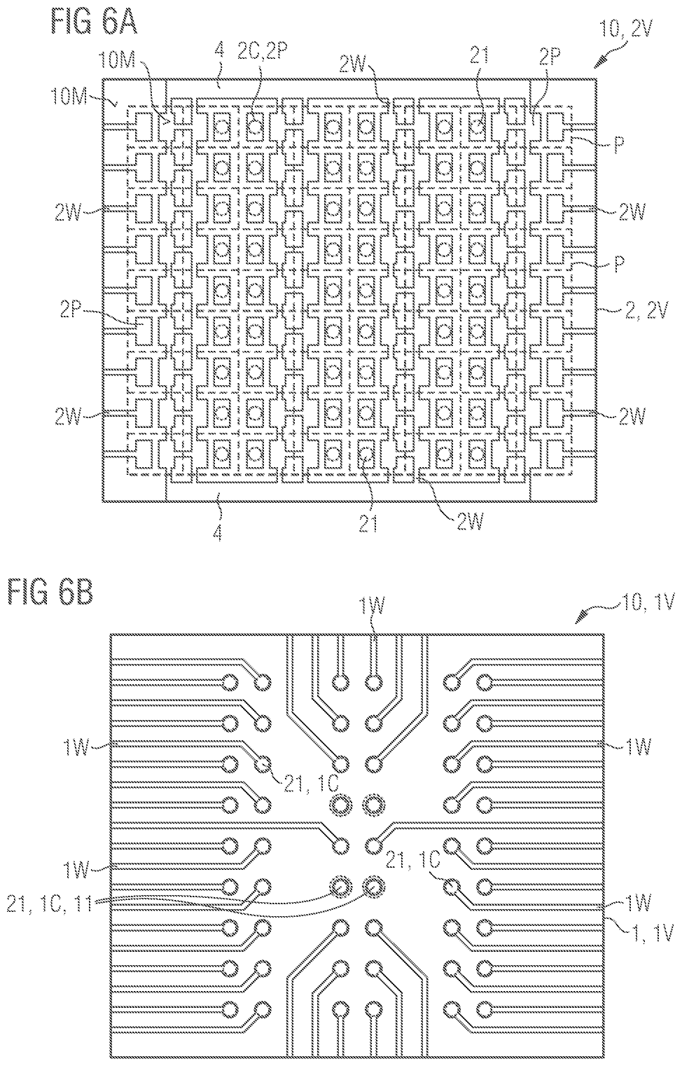

FIGS. 5A, 5B and 5C show examples of how the problem illustrated in FIG. 1E can be solved, in particular by using insulating layers 2 and 3 and associated through-vias 21 and 31. FIG. 5A shows a top view of a part of the mounting surface 10M and the wiring layer 2V of a carrier 10. FIG. 5B shows a vertical sectional view through a portion AB of the carrier 10. FIG. 5C shows a top view of the wiring layer 1V within the carrier 10, which corresponds to a lateral sectional view.

The mounting surface 10M has an arrangement of 8×4 connection pads 2P suitable for mounting 4×4 closely packed small bipolar components P. These may be, for example, light emitting diode flip chips.

Since the through-vias 21 within the insulating layer 2 have a smaller diameter 21D than the base through-vias 11 having diameter 11D, the smallest possible diameters of the closure caps 2C can be significantly smaller than the smallest possible diameters of the closure caps 1C.

Analogous to the explanation of FIG. 3C, a closure cap 2C could have a diameter 2CD of 80 μm, compared to a closure cap 1C with a diameter 1CD of 225 μm. For example, if a connection pad has a width of 80 μm, 100 μm, 150 μm or 200 μm as specified by component P, this allows integration of a closure cap 2C into a connection pad 2P, i.e. positioning of a connection pad 2P over a through-via 21, whereas this would not be possible in the example without an insulating layer in FIG. 1E.

Thus, all 8×4 connection pads 2P can be electrically wired inside the carrier 10. For example, the external 20 connection pads can be electrically wired per conductor tracks 2W in the wiring layer 2V as illustrated. The inner 12 connection pads 2P can, for example, as illustrated, first be electrically wired via the through-vias 21 to the wiring layer 1V and then from there with conductor tracks 1W (see FIG. 5C). The through-vias 11 and 31 as well as the wiring within the wiring layers 1R and 3R as shown in FIG. 5B may be present or optional.

In this way, the example illustrated in FIGS. 5A to 5C can be easily extended to a larger number of components P and connection pads 2P, respectively.

Starting from the outer upper wiring layer 2V, all possible connection pads 2P are wired in each case per conductor tracks 2W within this wiring layer. These are usually the connection pads on the outside in the field. The potentials of the other, in particular of all other connection pads are routed to the next lower wiring layer via the through-vias 21. These are usually the inner connection pads.

There, the process is then successive in each case. This means that the potentials, usually the external potentials, are wired by conductor tracks in this wiring layer. The wiring of all other potentials, usually the inner potentials, is realized by through-vias in a lower wiring layer. This is realized by a sufficient number of wiring layers until sufficiently few potentials remain in wiring layer 1V to be wired there by conductor tracks 1W or by the through-vias 11 in base substrate 1.

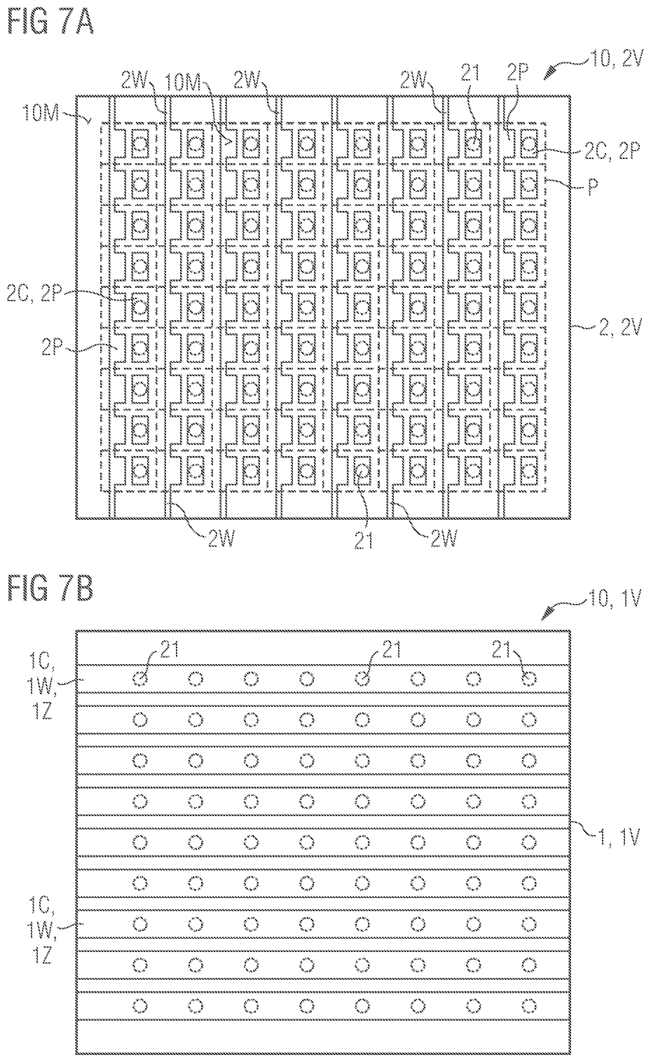

FIGS. 6A and 6B show, as an example of application, a closely packed arrangement of 16×9 connection pads 2P suitable for, for example, 8×9 closely packed bipolar small components P such as light emitting diode flip chips. The components are partially wired via a common electrode 4, which may be a common anode or common cathode of the carrier 10. The respective components P each have a connection pad which can be assigned to an individual potential and can be electrically wired separately, while the other connection pads of the components have a common potential and can all be electrically connected to each other.

FIG. 6A shows, analogously to FIG. 5A, a top view of a part of the mounting surface 10M and the wiring layer 2V of a carrier 10. FIG. 6B shows, analogously to FIG. 5C, a top view of the wiring layer 1V within the carrier 10 and thus a lateral sectional view of the carrier 10 at the vertical level of the wiring layer 1V. The vertical structure of the carrier 10 is the same as that of the carrier 10 shown in FIG. 5B.

Analogous to the explanation of FIG. 3C, a closure cap 2C could have a diameter 2CD of 80 μm, compared to a closure cap 1C having a diameter 1CD of 225 μm. For example, if a connection pad 2P has a width of 80 μm, 100 μm, 150 μm or 200 μm as specified by the component P, this allows integration of a closure cap 2C into a connection pad 2P, i.e. positioning of a connection pad 2P over a through-via 21, wherein this would not be possible in the example without an insulating layer in FIG. 1E.

Thus, all 16×9 connection pads 2P can be electrically wired within the carrier 10. The 72 connection pads with the same potential and 18 connection pads with individual potential are wired by conductor tracks 2W in the wiring layer 2V, as illustrated in FIG. 6A. The remaining 54 connection pads with individual potential cannot be wired within the wiring layer 2V due to space restrictions and are first connected to the wiring layer 1V via the through-vias 21. Here, 50 of these 54 connection pads are wired by conductor tracks 1W in wiring layer 1V, as illustrated in FIG. 6B. The remaining 4 connection pads cannot be wired within the wiring layer 1V due to limitations of space, and are first placed on the wiring layer 1R by the through-vias 11 to be wired there.

The application illustrated in FIGS. 6A to 6B can be extended to a larger number of components P and connection pads 2P, respectively, analogously to the exemplary embodiments of FIGS. 4D and 4E.

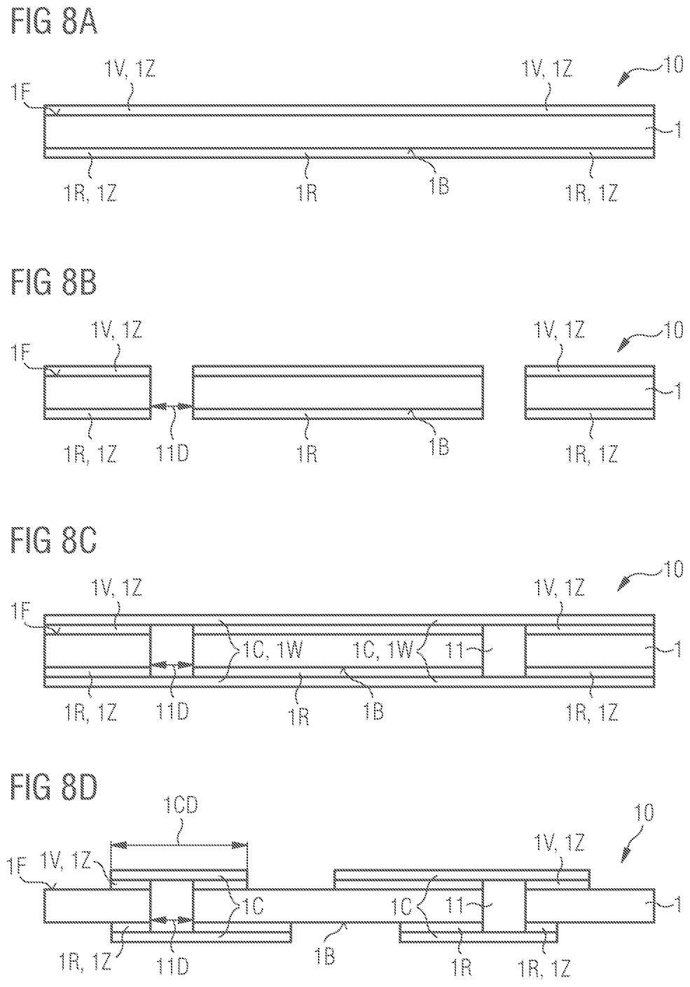

FIGS. 7A and 7B illustrate, as an example of application, a close-packed arrangement of 16×9 connection pads 2P suitable for, for example, 8×9 close-packed bipolar small components P such as light emitting diode flip chips. The mounting surface 10M or outer wiring layer 2V thus has a plurality of connection pads 2P arranged, in particular, in a matrix form with a plurality of rows and columns.

Referring to FIG. 7A, the connection pads 2P of each second column of the matrix arrangement are electrically connected to each other via a common conductive track 2W. In particular, the common conductor track 2W is in line with the corresponding connection pads 2P of the same column. In other words, the common conductor track 2W in particular does not project laterally beyond the associated connection pads 2P to the connection pads 2P of the adjacent column. In particular, exactly half of the connection pads 2P are wired over the conductor tracks 2W on the wiring layer 2V.

Those connection pads 2P which are not electrically connected or electrically wired via the conductor tracks 2W on the wiring layer 2V or on the mounting surface 10M, respectively, can be electrically wired via the through-vias 21 to the conductor tracks in a lower-lying wiring layer, in particular in the inner wiring layer 1V.

Analogously to the outer wiring layer 2V, the connection pads 2P of the same row, which are not already electrically wired via the conductor tracks 2W on the mounting surface 10M, are electrically conductively connected to each other via the conductor tracks 1W in the inner wiring layer 1V according to FIG. 7B. Thus, FIGS. 7A and 7B show a cross-matrix circuit on two different wiring layers. Each component P arranged on a pair of two connection pads 2P of different polarities can be individually activated via the conductor tracks 1W and 2W arranged on different wiring layers.

In all of the exemplary embodiments for a carrier 10 described so far, the conductor tracks 1W, 2W, 3W, the closure caps 1C, 2C, 3C, the connection pads 2P and/or 3P may be formed of a metal such as copper, nickel or aluminum. The cover layer 1Z of the base substrate 1 may also be formed of such a material. The insulating layers 2 and 3 may each be formed from a solder resist, a photoresist, a potting compound, silicon oxide or from silicon nitride. The maximum possible offset between the through-via 21 or 31 and the associated closure cap 2C or 3C is preferably less than 100 μm, 50 μm, for instance less than 30 μm, in particular less than 25 μm or less than 20 μm.

It is possible that further layers are used at the joining locations between two electrically conductive layers to improve electrical contact, to improve thermal contact, to improve mechanical strength or to suppress diffusion. Such further layers may be formed of titanium, platinum, palladium, tungsten nitride or alloys of these layers.

The connection pads 2P or 3P, which are configured for electrical contacting the component, and/or the contact points of the component can be formed from titanium, platinum, palladium, tungsten nitride, gold, tin, silver, copper or from aluminum or alloys thereof. If the insulating layer 2 or 3 has openings 20 or 30, wherein the contact connection pads 2P or 3P are accessible at least in places, the insulating layer 2 or 3 can project beyond the contact connection pad 2P or 3P along the vertical direction. The opening 20 or 30 may serve as a collecting basin for excess solder material.

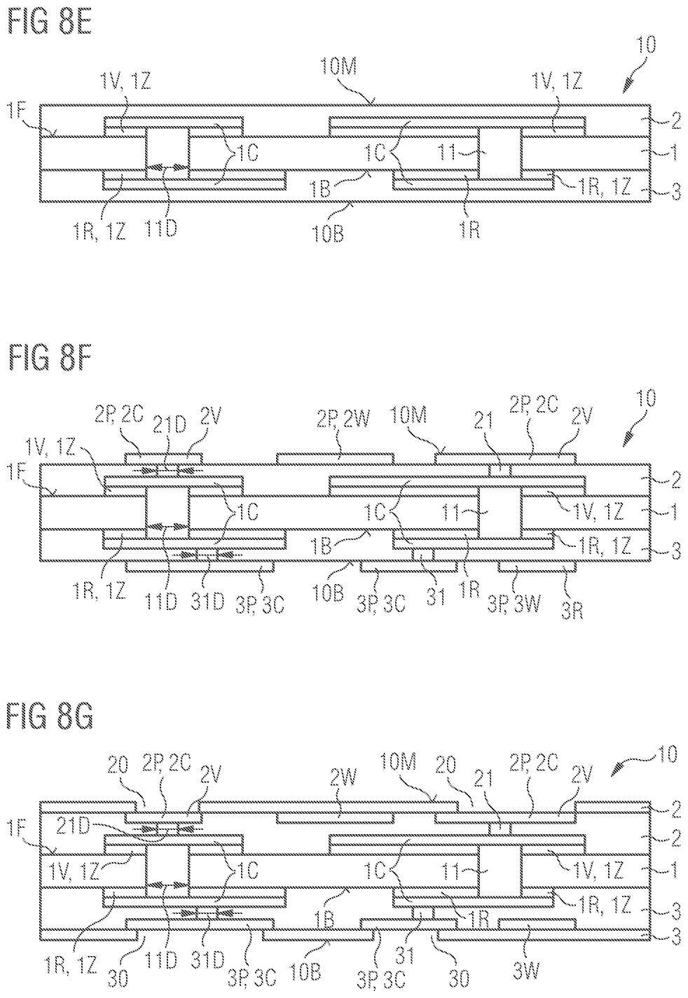

FIGS. 8A to 8G schematically illustrate various method steps of a method for producing a carrier 10.

According to FIG. 8A, a base substrate 1 is provided which has metallic coatings, in particular of copper, on both sides. The base substrate 1 may be formed from dielectric material of a printed circuit board. The base substrate has a front side 1F and a rear side 1B. A cover layer 1Z of the base substrate 1 is formed on the front side 1F and on the rear side 1B, respectively, by the metallic coating. In particular, the covering layer 1Z is partially provided to form a wiring layer 1V or 1R.

Referring to FIG. 8B, a plurality of openings for forming the through-vias 11 are formed which extend throughout the cover layer 1Z and the base substrate 1. The cross-section of the opening determines the cross-section 11D of the through-via 11.

Referring to FIG. 8C, the through-vias 11 are formed by filling the previously created openings. A closure layer 1C is also formed on the cover layer 1Z in each case. The closure layer 1C may be formed of copper. The closure layer 1C and the through-vias 11 may be formed of the same material or of different materials.

According to FIG. 8D, the cover layer 1Z and the closure layer 1C are structured on both sides of the base substrate 1. The closure layer 1C may be structured into a plurality of closure caps 1C, each of which completely covers at least one of the through-vias 11 in top view. The closure cap 1C has a diameter 1CD. By patterning the cover layer 1Z and the closure layer 1C, the base substrate 1 can be exposed in places.

According to FIG. 8E, an insulating layer 2 is applied to the front side 1F of the base substrate 1 and to the front-side closure caps 1C. The insulating layer 2 can completely cover the closure caps 1C and/or the base substrate 1 in top view. Analogous to the insulating layer 2, a further insulating layer 3 may be applied to the rear side 1B of the base substrate 1 and to the rear-side closure caps 1C. The insulating layers 2 and 3 can be produced in the same method step or in different method steps. The insulating layers 2 and 3 may be formed of the same material or of different materials.

According to FIG. 8F, openings are formed in the insulating layers 2 and 3 to form the through-vias 21 and 31. An outer wiring layer 2V with possible connection pads 2P, closure caps 2C and possible conductor tracks 2W is formed on the insulating layer 2. In particular, the inner closure caps 1C form an inner wiring layer 1V. Via the through-vias 21, the inner wiring layer 1V is electrically conductively connected to the outer wiring layer 2V.

Analogously to the through-vias 21 and to the outer wiring layer 2V on the front side 1F of the base substrate 1, a plurality of further through-vias 31 and an outer wiring layer 3R comprising a plurality of possible connection pads 3P, conductor tracks 3W and a plurality of possible closure caps 3C are formed on the rear side 1B of the base substrate 1. The exemplary embodiment shown in FIG. 8F corresponds to the exemplary embodiment of a carrier 10 shown in FIG. 4A.

According to FIG. 8G, a sub-layer of the insulating layer 2 or 3 is applied to the outer wiring layer 2V or 3R in such a way that the sub-layer partially covers the connection pads 2P or 3P and partially or, in particular, completely covers the conductor tracks 2W or 3W. The partial layer of the insulating layer 2 or 3 and the remaining part of the insulating layer 2 or 3 may be formed from the same material or from different materials. The partial layers can each have openings 20 or 30, wherein the connection pads 2P or 3P are at least partially accessible. The exemplary embodiment shown in FIG. 8G corresponds to the exemplary embodiment of a carrier 10 shown in FIG. 4B.

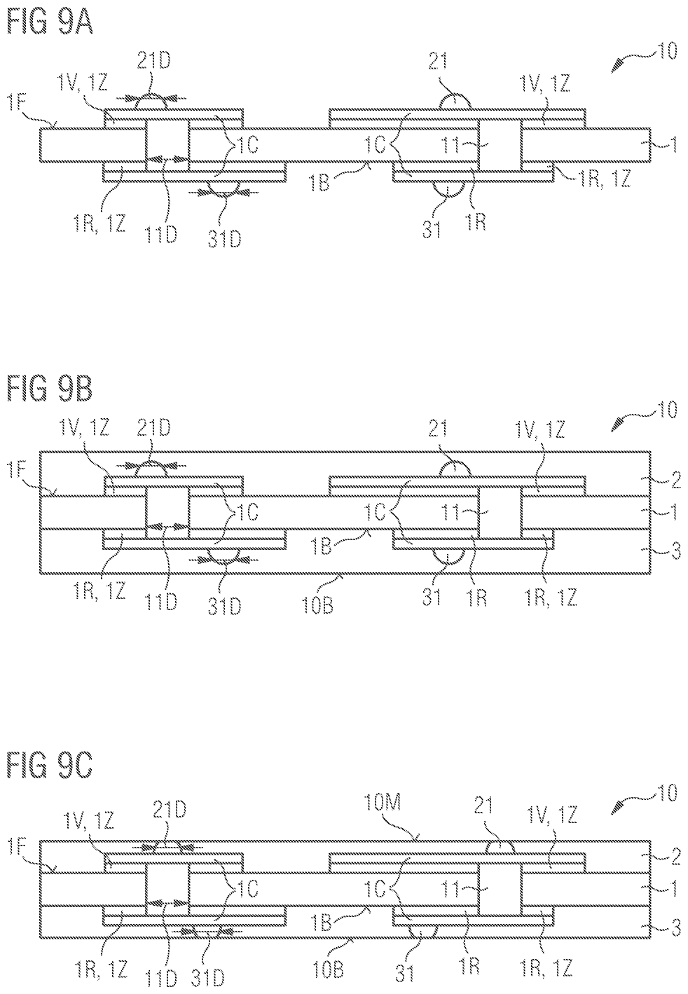

The exemplary embodiment illustrated in FIG. 9A essentially corresponds to the exemplary embodiment of a method step illustrated in FIG. 8D. In contrast, a plurality of electrically conductive interconnection structures, which are provided to form the through-vias 21 or 31, are applied onto the wiring layer 1V or onto the wiring layer 1R. The interconnection structures may be bond wires or are in the form of hemispheres. According to FIG. 9B, the insulating layer 2 and/or the insulating layer 3 is formed in such a way that it completely covers the through-vias 21 or 31.

According to FIG. 9C, the material of the insulating layer 2 and/or 3 is partially removed so that the through-vias 21 or 31 are exposed. In subsequent method steps, the outer wiring layer 2V or 3R can be formed on the insulating layer 2 or 3. This method is particularly suitable for the production of a carrier 10 shown, for example, in FIG. 2C or in FIG. 4C.

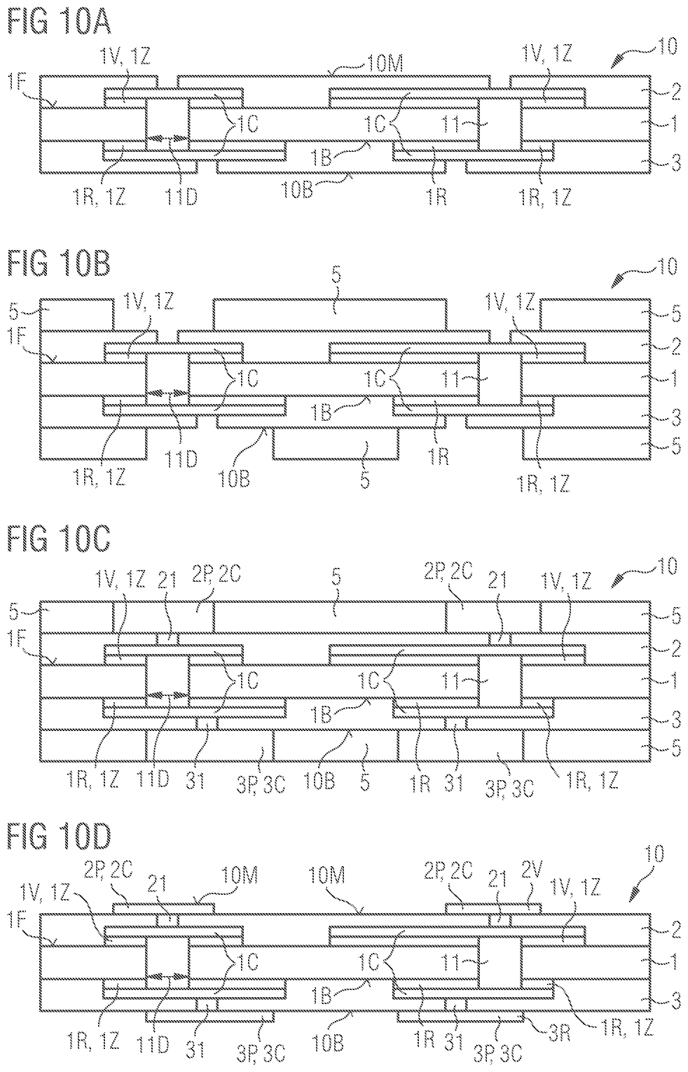

The exemplary embodiment shown in FIG. 10A is substantially the same as the exemplary embodiment for a method step shown in FIG. 8E. In contrast, the insulating layer 2 or 3 has a plurality of openings for forming the through-vias 21 or 31. The insulating layer 2 or 3 can be applied to the base substrate 1 in a structured manner. Alternatively, it is possible that the insulating layer 2 or 3 is first formed in a planar manner on the base substrate 1 and subsequently structured.

According to FIG. 10B, a sacrificial layer 5 is formed on the insulating layer 2 and/or 3, wherein in the regions of the openings of the insulating layer 2 or 3, the sacrificial layer 5 itself has openings. The openings of the sacrificial layer 5 have a larger cross-section than the openings of the insulating layer 2 and/or 3.

According to FIG. 10C, the openings of the insulating layer 2 or 3 and the openings of the sacrificial layer 5 are filled with an electrically conductive material. Through-vias 21 or 31 are formed inside the openings of the insulating layer 2 or 3. Outside the openings of the insulating layer 2 or 3 and inside the openings of the sacrificial layer 5, the front-side outer wiring layer 2V or the rear-side outer wiring layer 3R may be formed. The through-vias 21 and the connection pads 2P or the closure caps 2C of the front-side wiring layer 2V may be formed from the same material or from different materials. Similarly, the through-vias 31 and the connection pads 3P or the closure caps 3C of the outer wiring layer 3R may be formed from the same material or from different materials.

According to FIG. 10D, the sacrificial layer 5 is removed. The wiring layer 2V or 3R may be thinned, grinded or planarized. In particular, the sacrificial layer 5 is removed only after the corresponding wiring layer 2V or 3R has been thinned, grinded or planarized.

Using the method illustrated in FIGS. 10A to 10D, the shape, the layer thickness and/or the flanks of the through-vias 21 or 31 and the wiring layer 2V or 3R can be better controlled, for example, in comparison with an etching process, since the producing tolerances for patterning the sacrificial layer 5 are generally better than the producing tolerances, for example, for patterning an etching mask. Furthermore, an even more precise control can be achieved if the sacrificial layer 5 is formed to be transmissive to radiation, for instance transparent, or if an LDI process (laser direct imaging) and/or a so-called partitioning process is applied.

The invention is not restricted to the exemplary embodiments by the description of the invention made with reference to the exemplary embodiments. The invention rather comprises any novel feature and any combination of features, including in particular any combination of features in the claims, even if this feature or this combination is not itself explicitly indicated in the patent claims or exemplary embodiments.

1.-18. (canceled)

19. A carrier comprising:
a base substrate;
at least one insulating layer;
at least one inner wiring layer;
at least one outer wiring layer; and
at least one through-via in the insulating layer extending through the insulating layer,
wherein the base substrate and the insulating layer are formed from different materials,
wherein the base substrate is formed for mechanically stabilizing the carrier and supports the insulating layer,
wherein the inner wiring layer is arranged in a vertical direction at least in places between the base substrate and the insulating layer,
wherein the outer wiring layer is spatially separated from the inner wiring layer at least in places by the insulating layer, and
wherein the through-via electrically conductively connects the inner wiring layer to the outer wiring layer and has a lateral cross-section having a maximum lateral extent of at most 100 μm.

20. The carrier according to claim 19, wherein the inner wiring layer is arranged on the base substrate and is structured in such a way that the insulating layer is directly adjacent to the base substrate in places and directly adjacent to the inner wiring layer in places.

21. The carrier according to claim 19, further comprising a through-via in the base substrate, wherein the through-via extends through the base substrate, is electrically conductive and has a larger lateral cross-section than the through-via in the insulating layer.

22. The carrier according to claim 21, further comprising a further wiring layer, wherein the inner wiring layer and the further wiring layer are arranged on opposite surfaces of the base substrate and are electrically conductively connected to one another via the through-via in the base substrate.

23. The carrier according to claim 22, further comprising a further insulating layer, a further outer wiring layer and a further through-via in the further insulating layer extending through the further insulating layer, wherein the further wiring layer is formed as an inner wiring layer, wherein the base substrate is disposed in the vertical direction between the inner wiring layers as well as between the insulating layers, and wherein the further through-via electrically conductively connects the further inner wiring layer to the further outer wiring layer and has a lateral cross-section with a maximum lateral extent of at most 100 μm.

24. The carrier according to claim 19, wherein the through-via in the insulating layer has a lateral cross-section with a maximum lateral extent of at most 75 μm.

25. The carrier according to claim 19, wherein the through-via in the insulating layer has a lateral cross-section which decreases with increasing vertical distance from the base substrate.

26. The carrier according to claim 19,
wherein the inner wiring layer has an inner closure cap adjacent to the through-via in the base substrate and, in top view, completely covering this through-via,
wherein the outer wiring layer has an outer closure cap adjoining the through-via in the insulating layer and, in the top view, completely covering this through-via, and
wherein a maximum lateral offset between the outer closure cap and the through-via in the insulating layer is smaller than a maximum lateral offset between the inner closure cap and the through-via in the base substrate.

27. The carrier according to claim 19, wherein the outer wiring layer forms a freely accessible mounting surface configured to receive and electrically contact one electrical component or several electrical components.

28. The carrier according to claim 27, wherein the outer wiring layer has a plurality of conductor tracks and connection pads arranged next to one another, and wherein some of the connection pads are externally electrically connectable not via the through-vias in the insulating layer but exclusively via the conductor tracks of the outer wiring layer, and some further of the connection pads are electrically conductively connected to the inner wiring layer by the through-vias in the insulating layer.

29. The carrier according to claim 28,
wherein at least some adjacently arranged connection pads are arranged as pairs,
wherein, in each case, one connection pad of one pair is externally electrically connectable not via the through-via in the insulating layer but exclusively via at least one conductor track of the outer wiring layer, and
wherein the respective other connection pad of the one pair is electrically conductively connected to the inner wiring layer by a through-via in the insulating layer.

30. The carrier according to claim 19,
wherein the insulating layer and/or the further insulating layer is a layer of a potting compound, an oxide layer, a nitride layer, a polyimide layer, a solder resist layer or a photoresist layer, and/or
wherein the base substrate is a printed circuit board, a metal core board, a plastic body or a ceramic body.

31. The carrier according to claim 19,
wherein the outer wiring layer forms a freely accessible mounting surface configured to receive and to make electrical contact with one electrical component or with several electrical components,
wherein the outer wiring layer has a plurality of conductor tracks and connection pads arranged next to one another, and
wherein some of the connection pads are externally electrically connectable not via the through-vias in the insulating layer but exclusively via the conductor tracks of the outer wiring layer, and some further of the connection pads are electrically conductively connected to the inner wiring layer by the through-vias in the insulating layer.

32. The carrier according to claim 19,
wherein the outer wiring layer forms a freely accessible mounting surface configured to receive and to make electrical contact with one electrical component or with several electrical components,
wherein the outer wiring layer has a plurality of conductor tracks and connection pads arranged next to one another,
wherein some of the connection pads are externally electrically connectable not via the through-vias in the insulating layer but exclusively via the conductor tracks of the outer wiring layer, and some further of the connection pads are electrically conductively connected to the inner wiring layer by the through-vias in the insulating layer,
wherein some adjacently arranged connection pads are arranged as pairs,
wherein, in each case, one connection pad of one pair is externally electrically connectable not via the through-via in the insulating layer but exclusively via conductor track/s of the outer wiring layer, and the respective other connection pad of the one pair is electrically conductively connected to the inner wiring layer by a through-via in the insulating layer.

33. A method for producing the carrier according to claim 19,
wherein a method for forming the base substrate and a method for forming the insulating layer and/or the further insulating layer differ from each other.

34. The method according to claim 33, wherein the carrier comprises the through-via in the base substrate, wherein the through-via extends through the base substrate, is electrically conductive and has a larger lateral cross-section than the through-via in the insulating layer, and wherein a method for forming the through-via in the base substrate and a method for forming the through-via in the insulating layer differ from each other.

35. The method according to claim 33, further comprising:
applying an electrically insulating material to the inner wiring layer;
forming an opening in the insulating layer to partially expose the inner wiring layer; and
filling the opening with an electrically conductive material to form the through-via.

36. The method according to claim 33, further comprising:
applying an electrically conductive material onto the inner wiring layer in places for forming the through-via in the insulating layer prior to forming the insulating layer;
applying an electrically insulating material onto the inner wiring layer to form the insulating layer so that the insulating layer completely covers the through-via in top view; and
partially removing the insulating material of the insulating layer to expose the through-via.

37. A carrier comprising:
a base substrate;
at least one insulating layer;
at least one inner wiring layer;
at least one outer wiring layer; and
at least one through-via in the insulating layer extending through the insulating layer,
wherein the base substrate and the insulating layer are formed from different materials,
wherein the base substrate is formed for mechanically stabilizing the carrier and supports the insulating layer,
wherein the inner wiring layer is arranged in a vertical direction at least in places between the base substrate and the insulating layer,
wherein the outer wiring layer is spatially separated from the inner wiring layer at least in places by the insulating layer,
wherein the through-via electrically conductively connects the inner wiring layer to the outer wiring layer,
wherein the outer wiring layer forms a freely accessible mounting surface configured to receive and to make electrical contact with one electrical component or with several electrical components,
wherein the outer wiring layer has a plurality of conductor tracks and connection pads arranged next to one another, and
wherein some of the connection pads are externally electrically connectable not via the through-vias but exclusively via the conductor tracks of the outer wiring layer, and some further of the connection pads are electrically conductively connected to the inner wiring layer by the through-vias in the insulating layer.

38. A carrier comprising:
a base substrate;
at least one insulating layer;
at least one inner wiring layer;
at least one outer wiring layer; and
at least one through-via in the insulating layer extending through the insulating layer,
wherein the base substrate and the insulating layer are formed from different materials,
wherein the base substrate is formed for mechanically stabilizing the carrier and supports the insulating layer,
wherein the inner wiring layer is arranged in a vertical direction at least in places between the base substrate and the insulating layer,
wherein the outer wiring layer is spatially separated from the inner wiring layer at least in places by the insulating layer,
wherein the through-via electrically conductively connects the inner wiring layer to the outer wiring layer,
wherein the outer wiring layer forms a freely accessible mounting surface configured to receive and to make electrical contact with one electrical component or with several electrical components,
wherein the outer wiring layer has a plurality of conductor tracks and connection pads arranged next to one another,
wherein some of the connection pads are externally electrically connectable not via the through-vias but exclusively via the conductor tracks of the outer wiring layer, and some further of the connection pads are electrically conductively connected to the inner wiring layer by the through-vias in the insulating layer,
wherein some adjacently arranged connection pads are arranged as pairs, and
wherein in each case one connection pad of one pair is externally electrically connectable not via the through-via but exclusively via at least one conductor track of the outer wiring layer, and the respective other connection pad of the one pair is electrically conductively connected to the inner wiring layer by the through-via in the insulating layer.
